(19) United States
(12) Patent Application Publication
(10) Pub. No.: US 2017/0168090 A1
(43) Pub. Date: Jun. 15, 2017

(54) ADAPTER FOR POWER FACTOR CORRECTION OF AN ELECTRICAL SUPPLY SYSTEM

(71) Applicant: Rory Daniel Malisoff, Daytona Beach Shores, FL (US)

(72) Inventor: Rory Daniel Malisoff, Daytona Beach Shores, FL (US)

(21) Appl. No.: 14/968,771

(22) Filed: Dec. 14, 2015

(51) Int. Cl. G01R 1/04; G01R 11/17

(52) U.S. Cl. CPC G01R 1/0408; G01R 11/17

(57) ABSTRACT

The present disclosure provides an adapter. The adapter corrects a power factor of an electrical supply system. The adapter is configured to insert between an electrical utility power meter and a power meter socket of an electrical service panel. The adapter includes a frame. The frame is configured to plug into the electrical utility power meter. In addition, the adapter includes a plurality of socket jaws positioned inside the frame parallel to a longitudinal axis of the frame. Moreover, the adapter includes a plurality of jaw blades positioned on the bottom side of the frame parallel to the longitudinal axis of the frame. Further, the adapter includes an electrical circuit component for correction of the power factor of the electrical supply system. Furthermore, the adapter includes a plurality of protection elements placed adjacent to the electrical circuit component inside the frame of the adapter.

### INTRODUCTION

The present disclosure relates to a field of power factor correction. More specifically, the present disclosure relates to an adapter for correcting a power factor of an electrical supply system for reduction in power consumption and energy costs.

Electrical power systems deliver electrical power to various facilities such as residential complexes, buildings, offices and the like. These facilities include a large number of loads which consume the electrical power. These loads affect the performance and the efficiency of the AC electrical power systems. In general, the performance and the efficiency of the electrical power systems are based on a current value of power factor. In addition, the power factor of an AC electrical power system is a ratio of real power flowing to the load to the apparent power in the circuit. Moreover, the power factor is a dimensionless quantity in a range of 0 to 1.

Going further, the power factor of the AC electrical power system reduces due to a large value of apparent power. This large value of the apparent power is due to the inductive loads in the facilities. In addition, the reduction of the power factor leads to increased power consumption and energy costs for the consumers. So, there is a need to keep the power factor in check and close to a value of 1. Traditionally, the power factor is controlled by various power correction methods. These power correction methods are employed to raise the power factor of the AC electrical power systems.

In general, the power factor is controlled by utilizing a passive network of capacitors or inductors. These devices are installed in a central substation, power service entrance of the facilities and the like. In addition, these devices are built into power consuming equipment. Further, the power factor correction is achieved by switching in or switching out the banks of installed capacitors or inductors. Also, power factor correction equipment may be installed by the consumers in order to reduce the energy costs charged by distribution companies. Furthermore, the power factor correction methods cancel the inductive or capacitive effects for correcting the power factor. Moreover, these capacitors are plugged into an electrical service panel at the facilities. Also, these capacitors may be of a fixed value.

The existing methods and systems for the correction of the power factor of the AC electrical power system have certain drawbacks. The present systems and methods do not take into account an optimum value of capacitance needed for improving the power factor. In addition, the capacitor with a wrong value increases the electricity costs for the consumers due to an increase in power consumption. Moreover, the efficiency of the AC electrical power system decreases. Further, the present methods and systems do not take into account a type of loads in each of the facilities. Furthermore, the power correction equipment takes a large time to install in the facilities which increases the cost of labor.

In light of the above stated discussion, there is a need for a method and system that overcomes the above stated disadvantages.

### SUMMMARY

In an aspect of the present disclosure, the present disclosure provides an adapter. The adapter corrects a power factor of an electrical supply system. The adapter is configured to insert between an electrical utility power meter and a power meter socket of an electrical service panel. The adapter includes a frame. The frame is configured to plug into the electrical utility power meter. In addition, the adapter includes a plurality of socket jaws positioned inside the frame parallel to a longitudinal axis of the frame. Moreover, the adapter includes a plurality of jaw blades positioned on the bottom side of the frame parallel to the longitudinal axis of the frame. Further, the adapter includes an electrical circuit component for correction of the power factor of the electrical supply system. Furthermore, the adapter includes a plurality of protection elements placed adjacent to the electrical circuit component inside the frame of the adapter. Also, the adapter includes a plurality of wires. The plurality of wires connects the electrical circuit component with the power meter socket of the electrical service panel below through the corresponding plurality of jaw blades. In addition, the frame is cylindrical in shape. The frame includes a plurality of flanges. Each of the plurality of flanges securely plugs the frame between the electrical utility power meter and the power meter socket of the electrical service panel. Moreover, the plurality of flanges an upper flange positioned on a top side of the frame. The upper flange is configured to plug the frame into the electrical utility power meter from the top side. Further, the adapter includes a lower flange positioned on a bottom side of the frame. The lower flange is configured to plug the frame into the power meter socket of the electrical service panel from the bottom side. Further, each of the plurality of socket jaws is positioned in an inner hollow portion of the frame. Each socket jaw of the plurality of socket jaws is positioned at a pre-defined distance from another socket jaw of the plurality of socket jaws. Each of the plurality of socket jaws is configured to connect the top side of the frame to the electrical utility power meter. The plurality of socket jaw includes a first socket jaw, a second socket jaw, a third socket jaw and a fourth socket jaw. In addition, each jaw blade of the plurality of jaw blades is positioned at a pre-determined distance from another jaw blade of the plurality of jaw blades. Further, each of the plurality of jaw blades is configured to connect the bottom side of the frame with the power meter socket of the electrical service panel. Moreover, the electrical circuit component is mounted inside the frame adjacent to each of the plurality of socket jaws. Moreover, an electrical value of the electrical circuit component is determined based on a pre-determined criterion. Also, the electrical circuit component includes a plurality of electrical terminals. The plurality of electrical terminals includes a first electrical terminal and a second electrical terminal. The first electrical terminal is electrically connected to the first socket jaw of the plurality of socket jaws. The second electrical terminal is electrically connected to the second socket jaw of the plurality of socket jaw. Further, each of the plurality of protection elements is configured to connect the electrical circuit component with the corresponding first socket jaw and the second socket jaw.

In an embodiment of the present disclosure, a size of the frame is based on a size of the electrical utility power meter. The size of the frame enables the frame to fit into the electrical utility power meter.

In an embodiment of the present disclosure, the electrical utility power meter is secured to the adapter with a first holding ring.

In an embodiment of the present disclosure, the adapter is secured to the power meter socket of the electrical service panel with a second holding ring.

In an embodiment of the present disclosure, the adapter further includes a plurality of protective straps on the bottom side of the adapter. The plurality of protective straps prevents the first holding ring and the second holding ring from floating.

In an embodiment of the present disclosure, the adapter further includes a pigtail wire connection inside the frame. The pigtail wire connection includes a neutral lead electrically connected to ground on the adapter.

In an embodiment of the present disclosure, the adapter further includes a plurality of fittings on the bottom side of the adapter. Each of the plurality of fittings is placed parallel to the longitudinal axis of the adapter.

In an embodiment of the present disclosure, the plurality of jaw blades includes a first jaw blade, a second jaw blade, a third jaw blade and a fourth jaw blade.

In an embodiment of the present disclosure, the electrical circuit component for the correction of the power factor of the electrical supply system is a capacitor.

In an embodiment of the present disclosure, the electrical circuit component for the correction of the power factor of the electrical supply system is a plurality of capacitors.

In an embodiment of the present disclosure, the plurality of protection elements is configured to protect the adapter during over current condition.

In an embodiment of the present disclosure, the plurality of protection elements includes a first protection element and a second protection element.

In another embodiment of the present disclosure, the first protection element includes a first terminal and a second terminal.

In yet another embodiment of the present disclosure, the second protection element includes a third terminal and a fourth terminal.

In yet another embodiment of the present disclosure, the first protection element is electrically connected to the first electrical terminal of the capacitor and the first socket jaw. The first protection element is connected in series.

In yet another embodiment of the present disclosure, the first protection element is electrically connected to the first electrical terminal of each of the plurality of capacitors and the first socket jaw. The first protection element is connected in series.

In yet another embodiment of the present disclosure, the second protection element is electrically connected to the second electrical terminal of the electrical circuit component and the second socket jaw. The second protection element is connected in series.

In yet another embodiment of the present disclosure, the second protection element is electrically connected to the first electrical terminal of each of the plurality of capacitors and the second socket jaw. The second protection element is connected in series.

In yet another embodiment of the present disclosure, the pre-determined criterion for determination of the electrical value of the electrical circuit component is based on a determination of the power factor in real time. The adapter is installed when the power factor is greater than a pre-defined threshold value.

In another aspect of the present disclosure, the present disclosure provides an adapter. The adapter corrects a power factor of an electrical supply system. The adapter is configured to insert between an electrical utility power meter and a power meter socket of an electrical service panel. The adapter includes a frame. The frame is configured to plug into the electrical utility power meter. In addition, the adapter includes a plurality of socket jaws positioned inside the frame parallel to a longitudinal axis of the frame. Moreover, the adapter includes a plurality of jaw blades positioned on the bottom side of the frame parallel to the longitudinal axis of the frame. Further, the adapter includes an electrical circuit component for correction of the power factor of the electrical supply system. Furthermore, the adapter includes a plurality of protection elements placed adjacent to the electrical circuit component inside the frame of the adapter. Also, the adapter includes a plurality of wires. The plurality of wires connects the electrical circuit component with the power meter socket of the electrical service panel below through the corresponding plurality of jaw blades. Further, the adapter includes a plurality of holder rings. The plurality of holder rings includes a first holder ring and a second holder ring. Furthermore, the adapter includes a plurality of protective straps on the bottom side of the adapter. In addition, the frame is cylindrical in shape. The frame includes a plurality of flanges. Each of the plurality of flanges securely plugs the frame between the electrical utility power meter and the power meter socket of the electrical service panel. Moreover, the plurality of flanges an upper flange positioned on a top side of the frame. The upper flange is configured to plug the frame into the electrical utility power meter from the top side. Further, the adapter includes a lower flange positioned on a bottom side of the frame. The lower flange is configured to plug the frame into the power meter socket of the electrical service panel from the bottom side. Further, each of the plurality of socket jaws is positioned in an inner hollow portion of the frame. Each socket jaw of the plurality of socket jaws is positioned at a pre-defined distance from another socket jaw of the plurality of socket jaws. Each of the plurality of socket jaws is configured to connect the top side of the frame to the electrical utility power meter. The plurality of socket jaw includes a first socket jaw, a second socket jaw, a third socket jaw and a fourth socket jaw. In addition, each jaw blade of the plurality of jaw blades is positioned at a pre-determined distance from another jaw blade of the plurality of jaw blades. Further, each of the plurality of jaw blades is configured to connect the bottom side of the frame with the power meter socket of the electrical service panel. Moreover, the electrical circuit component is mounted inside the frame adjacent to each of the plurality of socket jaws. Moreover, an electrical value of the electrical circuit component is determined based on a pre-determined criterion. Also, the electrical circuit component includes a plurality of electrical terminals. The plurality of electrical terminals includes a first electrical terminal and a second electrical terminal. The first electrical terminal is electrically connected to the first socket jaw of the plurality of socket jaws. The second electrical terminal is electrically connected to the second socket jaw of the plurality of socket jaw. Further, each of the plurality of protection elements is configured to connect the electrical circuit component with the corresponding first socket jaw and the second socket jaw. In addition, the first holder ring secures the electrical utility power meter to the adapter. The second holder ring secures the adapter to the power meter socket of the electrical service panel. The plurality of protective straps prevents the first holding ring and the second holding ring from floating.

### BRIEF DESCRIPTION OF DRAWINGS

Having thus described the invention in general terms, reference will now be made to the accompanying drawings, which are not necessarily drawn to scale, and wherein:

FIG. 1A illustrates a perspective view of an adapter for power factor correction of an electrical supply system, in accordance with various embodiments of the present disclosure;

FIG. 1B illustrates a top view of the adapter for the power factor correction of the electrical supply system, in accordance with an embodiment of the present disclosure;

FIG. 1C illustrates a bottom view of the adapter for the power factor correction of the electrical supply system, in accordance with another embodiment of the present disclosure;

FIG. 2 illustrates a schematic diagram for insertion of the adapter between an electrical utility power meter and a service panel, in accordance with various embodiments of the present disclosure; and

FIG. 3 illustrates a perspective view of the adapter inserted between the electrical utility power meter and the service panel, in accordance with various embodiments of the present disclosure.

It should be noted that the accompanying figures are intended to present illustrations of exemplary embodiments of the present disclosure. These figures are not intended to limit the scope of the present disclosure. It should also be noted that accompanying figures are not necessarily drawn to scale.

### DETAILED DESCRIPTION

In the following description, for purposes of explanation, numerous specific details are set forth in order to provide a thorough understanding of the present technology. It will be apparent, however, to one skilled in the art that the present technology can be practiced without these specific details. In other instances, structures and devices are shown in block diagram form only in order to avoid obscuring the present technology.

Reference in this specification to “one embodiment” or “an embodiment” means that a particular feature, structure, or characteristic described in connection with the embodiment is included in at least one embodiment of the present technology. The appearance of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not for other embodiments.

Moreover, although the following description contains many specifics for the purposes of illustration, anyone skilled in the art will appreciate that many variations and/or alterations to said details are within the scope of the present technology. Similarly, although many of the features of the present technology are described in terms of each other, or in conjunction with each other, one skilled in the art will appreciate that many of these features can be provided independently of other features. Accordingly, this description of the present technology is set forth without any loss of generality to, and without imposing limitations upon, the present technology.

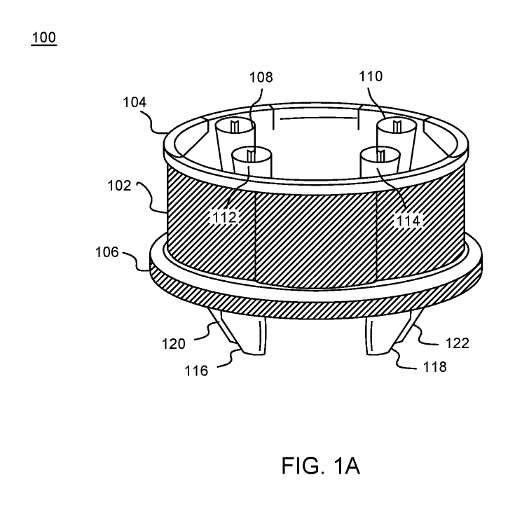

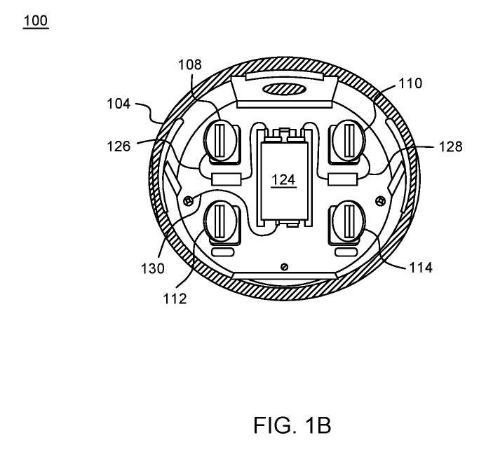

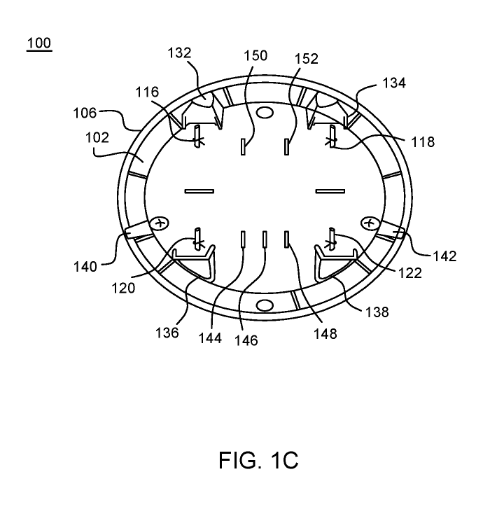

FIG. 1A illustrates a perspective view of an adapter 100 for power factor correction of an electrical supply system, in accordance with various embodiments of the present disclosure. The adapter 100 is configured to insert between an electrical utility power meter and a power meter socket of an electrical service panel. The electrical utility power meter is a device which measures an amount of electrical energy consumed by a residence, business and the like. In addition, the electrical utility power meter includes an electromechanical power meter and an electronic meter.

The electrical service panel is a steel box which holds a plurality of circuit breakers. Each of the plurality of circuit breakers is wired to a corresponding circuit that distributes power throughout the residence, building and the like. In addition, the power meter socket is a part of the electrical service panel. The power meter socket connects the electrical utility power meter to any facility. Further, the electrical supply system is a system which supplies the electrical energy to various facilities. The electrical energy is supplied for allowing residents, workers and the like to perform various tasks.

In an embodiment of the present disclosure, the electrical supply system supplies AC power to the facilities. Moreover, the electrical energy is distributed through various power distribution lines. The power distribution lines are a part of an electrical grid system. The electrical grid system produces, transmits and distributes the electrical power to the facilities through various electrical substations. Moreover, the electrical supply system includes a plurality of AC circuits. Further, the AC circuit is associated with a power factor. In general, the power factor corresponds to a ratio of real power used to do work to an apparent power supplied to the AC circuit.

Furthermore, the power factor of the AC circuits is between 0 and 1. Also, the power factor of the AC circuits is measured by ammeter-wattmeter-voltmeter method. Going further, the adapter 100 is a device configured to raise the power factor of the AC circuits to a higher value. In an embodiment of the present disclosure, the adapter 100 plugs between the electrical utility power meter and the meter socket of the electrical service panel. In addition, the adapter 100 enables an increased power factor, an increased efficiency, reduced power consumption, reduced energy costs and ease of installation.

Further, the adapter 100 is constructed by utilizing a heavy duty ABS plastic. Moreover, the ABS plastic (Acrylonitrile butadiene styrene) is a thermoplastic polymer made by polymerizing styrene and acrylonitrile in a presence of polybutadiene. In an embodiment of the present disclosure, the ABS plastic is utilized for providing high resistance and toughness to the adapter 100. In an embodiment of the present disclosure, the adapter 100 is sized to fit between the power meter socket and the corresponding electrical utility power meter.

In an embodiment of the present disclosure, the size of the adapter is based on a size of the electrical utility power meter. The size of the electrical utility power meter is a standard size. Further, the size of the adapter is kept close to the size of the electrical utility power meter. In an embodiment of the present disclosure, the adapter 100 fits into the electrical utility power meter in a strong manner. In an embodiment of the present disclosure, the adapter 100 is installed after removing the electrical utility power meter first. Accordingly, the adapter 100 is plugged from a bottom side to the meter socket and the electrical utility power meter is plugged onto a top side of the adapter 100.

In an embodiment of the present disclosure, the adapter 100 plugs into the meter socket by utilizing a plurality of components mounted on the adapter 100 (mentioned below in the patent application). In another embodiment of the present disclosure, the adapter 100 is uninstalled after detaching the electrical utility power meter from the top side of the adapter 100. Accordingly, the adapter 100 is detached from the meter socket. Moreover, the installation of the adapter 100 for a particular electrical service panel is done based on calculation of the power factor (explained below in the patent application).

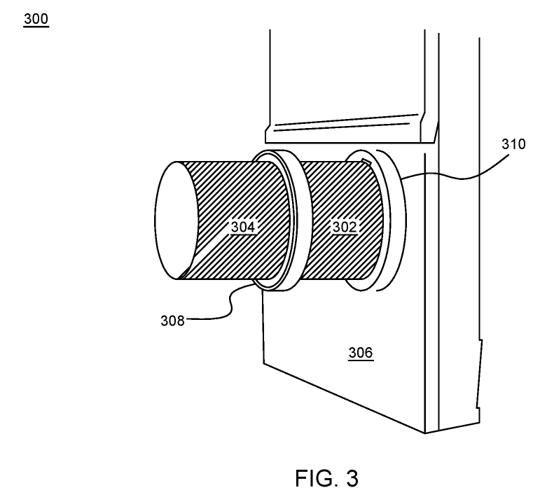

Going further, the adapter 100 includes a frame 102. The frame 102 is a round body configured to plug into the electrical utility power meter. In addition, the frame 102 is cylindrical in shape. In an embodiment of the present disclosure, the size of the frame is based on the size of the electrical utility power meter. Further, the frame 102 has a fixed diameter and fixed length. The diameter of the frame is determined based on a diameter of the electrical utility power meter. In addition, the frame 102 of the adapter 100 lies in line with the electrical utility power meter. In an embodiment of the present disclosure, the frame 102 and the electrical utility power meter form an extended cylindrical shape (as shown in the FIG. 3).

Further, the frame 102 of the adapter 100 includes a plurality of flanges. Each of the plurality of flanges securely plugs the frame 102 between the electrical utility power meter and the meter socket of the electrical service panel. In an embodiment of the present disclosure, each of the plurality of flanges is mounted on an outer circumference of the frame 102. Furthermore, the plurality of flanges includes an upper flange 104 and a lower flange 106. The upper flange 104 is positioned on a top side of the frame 102. In an embodiment of the present disclosure, the upper flange 104 is mounted on the top side of the frame 102. In addition, the upper flange 104 is configured to plug the frame 102 into the electrical utility power meter from the top side.

Furthermore, the lower flange 106 is positioned on a bottom side of the frame 102. In an embodiment of the present disclosure, the lower flange 106 is mounted on the bottom side of the frame 102. The lower flange 106 is configured to plug the frame 102 into the power meter socket of the electrical service panel from the bottom side. In an embodiment of the present disclosure, a diameter of the lower flange 106 is larger than a diameter of the upper flange 104. In an embodiment of the present disclosure, the electrical utility power meter is secured to the adapter 100 with a first holding ring. In an embodiment of the present disclosure, the adapter 100 is secured to the power meter socket of the electrical service panel with a second holding ring.

In an embodiment of the present disclosure, the first holding ring and the second holding ring are retainer rings. In an embodiment of the present disclosure, the first holding ring and the second holding ring tighten the fitting of the adapter with the electrical utility power meter and power meter socket. Going further, the adapter 100 includes a plurality of socket jaws. The plurality of socket jaws are positioned inside the frame 102 parallel to a longitudinal axis of the frame 102. In an embodiment of the present disclosure, the plurality of socket jaws face towards an opening of the adapter 100.

Further, in an embodiment of the present disclosure, each of the plurality of socket jaws is positioned in an inner hollow portion of the frame 102. In an embodiment of the present disclosure, each of the plurality of socket jaws is mounted up right inside the frame. Moreover, each socket jaw of the plurality of socket jaws is positioned at a pre-defined distance from another socket jaw of the plurality of socket jaws. In an embodiment of the present disclosure, the pre-defined distance is based on connection mechanism on the electrical utility power meter.

Each of the plurality of socket jaws is configured to connect the top side of the frame 102 to the electrical utility power meter. In an embodiment of the present disclosure, each of the plurality of socket jaws is fixed inside the frame 102. Moreover, in an embodiment of the present disclosure, the plurality of socket jaws may be of any size. Further, the plurality of socket jaws includes a first socket jaw 108, a second socket jaw 110, a third socket jaw 112 and a fourth socket jaw 114. In an embodiment of the present disclosure, the first socket jaw 108, the second socket jaw 110, the third socket jaw 112 and the fourth socket jaw 114 are parallel to the longitudinal axis of the adapter 100.

Going further, the adapter 100 includes a plurality of jaw blades. Each of the plurality of jaw blades is positioned on the bottom side of the frame 102 parallel to the longitudinal axis of the frame 102. In addition, each jaw blade of the plurality of jaw blades is positioned at a pre-determined distance from another jaw blade of the plurality of jaw blades. Further, each of the plurality of jaw blades is configured to connect the bottom side of the frame 102 of the adapter 100 with the power meter socket of the electrical service panel.

In an embodiment of the present disclosure, each of the plurality of jaw blades plug inside a corresponding socket jaw of another plurality of socket jaws on the power meter socket of the electrical service panel. In an embodiment of the present disclosure, the pre-determined distance between each of the plurality of jaw blades is determined based on a pre-defined criterion. The pre-defined criterion is based on a distance between each of another plurality of socket jaws of the power meter socket of the electrical service panel. Moreover, in an embodiment of the present disclosure, the plurality of jaw blades may be of any size.

Further, the plurality of jaw blades includes a first jaw blade 116, a second jaw blade 118, a third jaw blade 118 and a fourth jaw blade 120. In an embodiment of the present disclosure, the first jaw blade 116, the second jaw blade 118, the third jaw blade 118 and the fourth jaw blade 120 are parallel to the longitudinal axis of the adapter 100. Further, the adapter 100 includes additional components inside the frame 102 and on the bottom side of the frame 102 (discussed below in the detailed description of the FIG. 1A and FIG. 1B).

It may be noted that in FIG. 1A, the adapter 100 includes the first socket jaw 108, the second socket jaw 110, the third socket jaw 112 and the fourth socket jaw 114; however, those skilled in the art would appreciate that there are more number of socket jaws on the top side of the adapter 100. Also, it may be noted that in FIG. 1A, the adapter 100 includes the first jaw blade 116, the second jaw blade 118, the third jaw blade 118 and the fourth jaw blade 120; however, those skilled in the art would appreciate that there are more number of jaw blades on the bottom side of the adapter 100.

FIG. 1B illustrates a top view of the adapter 100 for the power factor correction of the electrical supply system, in accordance with an embodiment of the present disclosure. It may be noted that to explain the structural elements of the FIG. 1B, references will be made to the structural elements of the FIG. 1A. In an embodiment of the present disclosure, the top view of the adapter 100 shows a meter adapter side. Moreover, the top side of the adapter 100 is connected to a base of the electrical utility power meter.

Going further, the top side of the adapter 100 includes the plurality of socket jaws. The plurality of socket jaws includes the first socket jaw 108, the second socket jaw 110, the third socket jaw 112 and the fourth socket jaw 114 (as explained above in the detailed description of the FIG. 1A). In addition, the top side of the adapter 100 includes an electrical circuit component 124. The electrical circuit component 124 is configured for correction of the power factor of the electrical supply system. Moreover, the electrical circuit component 120 is mounted inside the frame 102 adjacent to each of the plurality of socket jaws.

Further, an electrical value of the electrical circuit component 124 is determined based on a pre-determined criterion. In an embodiment of the present disclosure, the electrical value corresponds to a capacitance value. The pre-determined criterion for determination of the electrical value of the electrical circuit component 124 is based on a determination of the power factor in real time. Moreover, the adapter 100 is installed when the power factor is greater than a pre-defined threshold value. In an embodiment of the present disclosure, the adapter 100 is installed based on a decision whether the adapter 100 is required for a particular facility or not.

Also, the electrical circuit component 124 includes a plurality of electrical terminals. The plurality of electrical terminals includes a first electrical terminal and a second electrical terminal. The first electrical terminal is electrically connected to the first socket jaw 108 of the plurality of socket jaws. The second electrical terminal is electrically connected to the second socket jaw 110 of the plurality of socket jaw.

Furthermore, in an embodiment of the present disclosure, the electrical circuit component 124 for the correction of the power factor of the electrical supply system is a capacitor. In another embodiment of the present disclosure, the electrical circuit component 124 for the correction of the power factor of the electrical supply system is a plurality of capacitors. In addition, each of the plurality of capacitors includes the first electrical terminal and the second electrical terminal. Moreover, the capacitor is an electrical component for storing the electrical energy.

Going further, the top side of the adapter 100 includes a plurality of protection elements. The plurality of protection elements are placed adjacent to the electrical circuit component 124 inside the frame 102 of the adapter 100. Each of the plurality of protection elements is configured to connect the electrical circuit component 124 with the corresponding first socket jaw 108 and the second socket jaw 110. In an embodiment of the present disclosure, the electrical circuit component is indirectly connected to the first socket jaw 108 and the second socket jaw 110.

In an embodiment of the present disclosure, each of the plurality of protection elements is configured to protect the adapter during over current condition. In addition, the plurality of protection elements includes a first protection element and a second protection element. The first protection element and the second protection element are mounted in a vicinity of the electrical component 120. Further, the first protection element includes a first terminal and a second terminal. Furthermore, the second protection element includes a third terminal and a fourth terminal.

The first protection element is electrically connected to the first electrical terminal of the capacitor 124 and the first socket jaw 108. The first protection element is connected in series. In an embodiment of the present disclosure, the first terminal of the first protection element is electrically connected to the first electrical terminal of the capacitor 124 and the first socket jaw 108. In an embodiment of the present disclosure, the first protection element is electrically connected in series to the first electrical terminal of each of the plurality of capacitors and the first socket jaw 108.

Further, the second protection element is electrically connected to the second electrical terminal of the electrical circuit component 124 and the second socket jaw 110. In addition, the second protection element is connected in series. In an embodiment of the present disclosure, the second protection element is electrically connected in series to the first electrical terminal of each of the plurality of capacitors and the second socket jaw 110.

Going further, the adapter 100 includes a plurality of wires. The plurality of wires connects the electrical circuit component 124 with the power meter socket of the electrical service panel below through the corresponding plurality of jaw blades. In addition, the plurality of wires includes a first wire 126 and a second wire 128. Moreover, the adapter 100 includes a pigtail wire connection inside the frame 102. The pigtail wire connection includes a neutral lead 130 electrically connected to ground on the adapter 100.

FIG. 1C illustrates a bottom view of the adapter 100 for the power factor correction of the electrical supply system, in accordance with another embodiment of the present disclosure. It may be noted that to explain the structural elements of the FIG. 1C, references will be made to the structural elements of the FIG. 1A and FIG. 1B. In an embodiment of the present disclosure, the bottom view of the adapter 100 shows a base adapter side. Moreover, the bottom side of the adapter 100 is connected to the power meter socket of the electrical service panel.

Going further, the bottom side of the adapter 100 includes the plurality of jaw blades. The plurality of jaw blades includes the first jaw blade 116, the second jaw blade 118, the third jaw blade 118 and the fourth jaw blade 120 (as explained above in the detailed description of the FIG. 1A). In addition, the adapter 100 includes a plurality of fittings on the bottom side of the adapter 100. Each of the plurality of fittings is placed parallel to the longitudinal axis of the adapter 100. Further, the plurality of fittings includes a first fitting 132, a second fitting 134, a third fitting 136 and a fourth fitting 138.

In an embodiment of the present disclosure, the plurality of fittings corresponds to a plurality of bosses for fixing the adapter 100 to the power meter socket. Further, the adapter 100 includes a plurality of protective straps on the bottom side of the adapter 100. The plurality of protective straps prevents the first holding ring and the second holding ring from floating. Also, the plurality of protective straps prevent hazard. In an embodiment of the present disclosure, each of the plurality of protection straps corresponds to a grounding strap.

Further, the plurality of protection straps includes a first protection strap 140 and a second protection strap 142. In addition, the adapter 100 includes a plurality of openings on the bottom side of the adapter 100. The plurality of openings is provided for installing more number of jaw blades and socket jaws when required. In an embodiment of the present disclosure, the plurality of openings acts as spare openings. Moreover, the plurality of openings include a first opening 144, a second opening 146, a third opening 148, a fourth opening 150 and a fifth opening 152.

The first opening 144, the second opening 146 and the third opening 148 are provided on one side of the adapter 100. Also, the first opening 144, the second opening 146 and the third opening 148 are parallel to each other. Further, the fourth opening 150 and the fifth opening 152 are provided on another side of the adapter 100. Furthermore, the fourth opening 150 and the fifth opening 152 are parallel to each other.

It may be noted that in FIG. 1C, the bottom side of the adapter 100 includes the first opening 144, the second opening 146, the third opening 148, the fourth opening 150 and the fifth opening 152; however, those skilled in the art would appreciate that there are more number of openings on the bottom side of the adapter 100. Also, it may be noted that in FIG. 1C, the adapter 100 includes the first protection strap 140 and the second protection strap 142 on the bottom side; however, those skilled in the art would appreciate that there are more number of protection straps on the bottom side of the adapter 100. Further, it may be noted that the bottom side of the adapter 100 includes the first fitting 132, the second fitting 134, the third fitting 136 and the fourth fitting 138; however, those skilled in the art would appreciate that there are more number of fittings on the bottom side of the adapter 100.

In an embodiment of the present disclosure, the present disclosure includes a method for the determination of the capacitance value for the installation of the adapter 100. In an embodiment of the present disclosure, the adapter 100 is installed after determining whether there is a need for the adapter 100 for a current facility. Moreover, the method includes a plurality of steps. In addition, a first step of the plurality of steps is to gather a plurality of materials and equipment. The plurality of materials and equipment include a power factor meter and one or more panel units. The power factor meter measures the power factor on a type of panel used.

Further, a second step of the plurality of steps is determination of the type of a panel unit. In an embodiment of the present disclosure, an initial test is conducted for the determination of the type of panel unit. The test is conducted based on a number of phases in the one or more panel units. Furthermore, a third step of the plurality of steps is to determine a number of loads on each of the one or more panels which are inductive. In an embodiment of the present disclosure, purely resistive loads are switched off during the third step.

Going further, a fourth step of the plurality of steps is measurement of the power factor for each of the one or more panels. Accordingly, a fourth step of the plurality of steps involves turning on a 240 volt inductive load. The inductive load includes an air conditioner, a pool pump and the like. Accordingly, the power factor is checked to determine whether the adapter 100 will provide a benefit to the facility or not. Further, a panel unit is installed based on a size of a main breaker and a number of phases of the one or more panels if the adapter 100 is of any benefit to the facility.

Accordingly, a measurement is done with the 240 V inductive loads. In addition, the correct adapter 100 for the one or more panels is chosen if the power factor remains higher than 0.90. In an embodiment of the present disclosure, the current method can be utilized for three phase application.

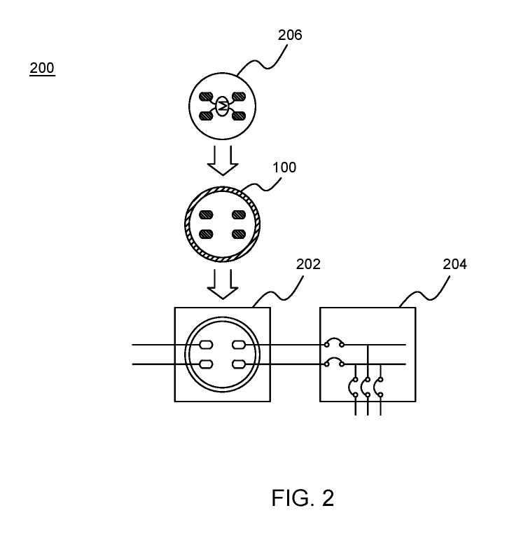

FIG. 2 a schematic diagram for insertion of the adapter 100 between an electrical utility power meter and a service panel, in accordance with various embodiments of the present disclosure. The schematic diagram shows the adapter 100, a conventional power meter socket 202, an electrical service panel 204 and an electrical utility power meter 206. The adapter 100 makes use of the conventional power meter socket 202 and the electrical service panel 204. In an embodiment of the present disclosure, the electrical service panel 204 can be mounted inside a wall.

Further, the electrical utility power meter 206 measures the electrical power usage of the facility for billing purposes. In an embodiment of the present disclosure, the system does not disturb a pre-existing system of the conventional power meter socket 202, the electrical service panel 204 and the electrical utility power meter 106. The adapter 100 inserts between the conventional power meter socket 202 of the electrical service panel 204 and the electrical utility power meter 206 (as described above in the patent application).

FIG. 3 illustrates a perspective view of the adapter 100 inserted between the electrical utility power meter and the electrical service panel, in accordance with various embodiments of the present disclosure. In an embodiment of the present disclosure, the FIG. 3 illustrates an adapter 302 installed between an electrical utility power meter 304 and an electrical service panel 306. In an embodiment of the present disclosure, the adapter 302 is the adapter 100. Moreover, the electrical utility power meter 304 is secured to the adapter 302 with a first holder ring 308. In addition, the adapter 302 is secured to the electrical service panel 306 with a second holder ring 310.

The present disclosure provides numerous advantages over the prior art. The present disclosure provides an adapter which increases the power factor of the electrical supply system. In addition, the present disclosure increases the efficiency of the electrical supply system. Moreover, the present disclosure reduces the power consumption. Further, the present disclosure reduces the energy costs for the consumers. Furthermore, the present disclosure reduces a time of installation of the adapter. Also, the installation of the adapter is easy. Further, the adapter can be installed in under two minutes.

The foregoing descriptions of specific embodiments of the present technology have been presented for purposes of illustration and description. They are not intended to be exhaustive or to limit the present technology to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is understood that various omissions and substitutions of equivalents are contemplated as circumstance may suggest or render expedient, but such are intended to cover the application or implementation without departing from the spirit or scope of the claims of the present technology.

While several possible embodiments of the invention have been described above and illustrated in some cases, it should be interpreted and understood as to have been presented only by way of illustration and example, but not by limitation. Thus, the breadth and scope of a preferred embodiment should not be limited by any of the above-described exemplary embodiments.

What is claimed is:

1. An adapter for correcting a power factor of an electrical supply system, the adapter being configured to insert between an electrical utility power meter and a power meter socket of an electrical service panel, the adapter comprising:
a frame configured to plug into the electrical utility power meter, wherein the frame being cylindrical in shape, wherein the frame comprises a plurality of flanges for securely plugging the frame between the electrical utility power meter and the power meter socket of the electrical service panel, wherein the plurality of flanges comprises:
an upper flange positioned on a top side of the frame, wherein the upper flange being configured to plug the frame into the electrical utility power meter from the top side; and
a lower flange positioned on a bottom side of the frame, wherein the lower flange being configured to plug the frame into the power meter socket of the electrical service panel from the bottom side;
a plurality of socket jaws positioned inside the frame parallel to a longitudinal axis of the frame, wherein each of the plurality of socket jaws being positioned in an inner hollow portion of the frame, wherein each socket jaw of the plurality of socket jaws being positioned at a pre-defined distance from another socket jaw of the plurality of socket jaws, wherein each of the plurality of socket jaws being configured to connect the top side of the frame to the electrical utility power meter, wherein the plurality of socket jaw comprises:
a first socket jaw;
a second socket jaw;
a third socket jaw; and
a fourth socket jaw;
a plurality of jaw blades positioned on the bottom side of the frame parallel to the longitudinal axis of the frame, wherein each jaw blade of the plurality of jaw blades being positioned at a pre-determined distance from another jaw blade of the plurality of jaw blades, wherein each of the plurality of jaw blades being configured to connect the bottom side of the frame with the power meter socket of the electrical service panel;
an electrical circuit component for correction of the power factor of the electrical supply system, wherein the electrical circuit component being mounted inside the frame adjacent to each of the plurality of socket jaws, wherein an electrical value of the electrical circuit component being determined based on a pre-determined criterion, wherein the electrical circuit component comprises a plurality of electrical terminals, wherein the plurality of electrical terminals comprises:
a first electrical terminal electrically connected to the first socket jaw of the plurality of socket jaws; and
a second electrical terminal electrically connected to the second socket jaw of the plurality of socket jaw;
a plurality of protection elements placed adjacent to the electrical circuit component inside the frame of the adapter, wherein each of the plurality of protection elements being configured to connect the electrical circuit component with the corresponding first socket jaw and the second socket jaw; and
a plurality of wires configured to connect the electrical circuit component with the power meter socket of the electrical service panel below through the corresponding plurality of jaw blades.

2. The adapter as recited in claim 1, wherein a size of the frame being based on a size of the electrical utility power meter and wherein the size of the frame enables the frame to fit into the electrical utility power meter.

3. The adapter as recited in claim 1, wherein the electrical utility power meter being secured to the adapter with a first holding ring.

4. The adapter as recited in claim 1, wherein the adapter being secured to the power meter socket of the electrical service panel with a second holding ring.

5. The adapter as recited in claim 1, further comprising a plurality of protective straps on the bottom side of the adapter and wherein the plurality of protective straps prevent the first holding ring and the second holding ring from floating.

6. The adapter as recited in claim 1, further comprising a pigtail wire connection inside the frame, wherein the pigtail wire connection comprises a neutral lead electrically connected to ground on the adapter.

7. The adapter as recited in claim 1, further comprising a plurality of fittings on the bottom side of the adapter, wherein each of the plurality of fittings being placed parallel to the longitudinal axis of the adapter.

8. The adapter as recited in claim 1, wherein the plurality of jaw blades comprises a first jaw blade, a second jaw blade, a third jaw blade and a fourth jaw blade.

9. The adapter as recited in claim 1, wherein the electrical circuit component for the correction of the power factor of the electrical supply system being a capacitor.

10. The adapter as recited in claim 1, wherein the electrical circuit component for the correction of the power factor of the electrical supply system being a plurality of capacitors.

11. The adapter as recited in claim 1, wherein the plurality of protection elements being configured to protect the adapter during over current condition.

12. The adapter as recited in claim 1, wherein the plurality of protection elements comprises a first protection element and a second protection element.

13. The adapter as recited in claim 12, wherein the first protection element comprises a first terminal and a second terminal.

14. The adapter as recited in claim 12, wherein the second protection element comprises a third terminal and a fourth terminal.

15. The adapter as recited in claim 12, wherein the first protection element being electrically connected to the first electrical terminal of the capacitor and the first socket jaw, wherein the first protection element being connected in series.

16. The adapter as recited in claim 12, wherein the first protection element being electrically connected to the first electrical terminal of each of the plurality of capacitors and the first socket jaw, wherein the first protection element being connected in series.

17. The adapter as recited in claim 12, wherein the second protection element being electrically connected to the second electrical terminal of the electrical circuit component and the second socket jaw, wherein the second protection element being connected in series.

18. The adapter as recited in claim 12, wherein the second protection element being electrically connected to the first electrical terminal of each of the plurality of capacitors and the second socket jaw, wherein the second protection element being connected in series.

19. The adapter as recited in claim 1, wherein the pre-determined criterion for determining the electrical value of the electrical circuit component being based on a determination of the power factor in real time, wherein the adapter being installed when the power factor being greater than a pre-defined threshold value.

20. An adapter for correcting a power factor of an electrical supply system, the adapter being configured to insert between an electrical utility power meter and a power meter socket of an electrical service panel, the adapter comprising:
a frame configured to plug into the electrical utility power meter, wherein the frame being cylindrical in shape, wherein the frame comprises a plurality of flanges for securely plugging the frame between the electrical utility power meter and the power meter socket of the electrical service panel, wherein the plurality of flanges comprises:
an upper flange positioned on a top side of the frame, wherein the upper flange being configured to plug the frame into the electrical utility power meter from the top side; and
a lower flange positioned on a bottom side of the frame, wherein the lower flange being configured to plug the frame into the power meter socket of the electrical service panel from the bottom side;
a plurality of socket jaws positioned inside the frame parallel to a longitudinal axis of the frame, wherein each of the plurality of socket jaws being positioned in an inner hollow portion of the frame, wherein each socket jaw of the plurality of socket jaws being positioned at a pre-defined distance from another socket jaw of the plurality of socket jaws, wherein each of the plurality of socket jaws being configured to connect the top side of the frame to the electrical utility power meter, wherein the plurality of socket jaw comprises:
a first socket jaw;
a second socket jaw;
a third socket jaw; and
a fourth socket jaw;
a plurality of jaw blades positioned on the bottom side of the frame parallel to the longitudinal axis of the frame, wherein each jaw blade of the plurality of jaw blades being positioned at a pre-determined distance from another jaw blade of the plurality of jaw blades, wherein each of the plurality of jaw blades being configured to connect the bottom side of the frame with the power meter socket of the electrical service panel;
an electrical circuit component for correction of the power factor of the electrical supply system, wherein the electrical circuit component being mounted inside the frame adjacent to each of the plurality of socket jaws, wherein an electrical value of the electrical circuit component being determined based on a pre-determined criterion, wherein the electrical circuit component comprises a plurality of electrical terminals, wherein the plurality of electrical terminals comprises:
a first electrical terminal electrically connected to the first socket jaw of the plurality of socket jaws; and
a second electrical terminal electrically connected to the second socket jaw of the plurality of socket jaw;
a plurality of protection elements placed adjacent to the electrical circuit component inside the frame of the adapter, wherein each of the plurality of protection elements being configured to connect the electrical circuit component with the corresponding first socket jaw and the second socket jaw;
a plurality of wires configured to connect the electrical circuit component with the power meter socket of the electrical service panel below through the corresponding plurality of jaw blades;
a plurality of holder rings comprising a first holder ring and a second holder ring, wherein the first holder ring secures the electrical utility power meter to the adapter and wherein the second holder ring secures the adapter to the power meter socket of the electrical service panel; and
a plurality of protective straps on the bottom side of the adapter, wherein the plurality of protective straps prevent the first holding ring and the second holding ring from floating.
